(19) United States
(12) Patent Application Publication
(10) Pub. No.: US 2024/0381578 A1
(43) Pub. Date: Nov. 14, 2024

(54) POWER-SUPPLY BOX FOR VEHICLE

(71) Applicant: Yazaki Corporation, Tokyo (JP)

(72) Inventors: Kazuomi Kiyosue, Makinohara-shi (JP); Akinori Nakashima, Makinohara-shi (JP); Dai Arani, Makinohara-shi (JP)

(73) Assignee: Yazaki Corporation, Tokyo (JP)

(21) Appl. No.: 18/656,195

(22) Filed: May 6, 2024

(30) Foreign Application Priority Data
May 10, 2023 (JP) 2023-077727

(51) Int. Cl. H05K 7/20; B60R 16/03; H05K 7/14

(52) U.S. Cl. CPC H05K 7/20409; B60R 16/03; H05K 7/14322

(57) ABSTRACT

A power-supply box for a vehicle includes a circuit board on which a part is mounted, and a heatsink that is thermally contacted with the part on the circuit board to radiate the heat of the part. The part produces heat when a power supply output is supplied to the part. The heatsink is made of resin and a metal plating layer is formed on a surface of the heatsink.

### CROSS REFERENCE TO RELATED APPLICATION

The present application is based on, and claims priority from the prior Japanese Patent Application No. 2023-077727, filed on May 10, 2023, the entire contents of which are incorporated herein by reference.

### TECHNICAL FIELD

The present disclosure relates to a power-supply box for a vehicle.

### BACKGROUND

Electrical power is supplied from a battery or an alternator that serves as a main power-supply to loads such as various electrical components (including ECU's) through wire harnesses in a vehicle. It also needed to distribute the electrical power of the main power-supply to plural electrical systems, to control the supply of the electrical power with respect to each of the systems, and to protect circuits against anomaly such as overcurrent. Therefore, a device, which is called as “junction box”, “fuse box” or “power-supply box”, is generally provided between the main power-supply and many loads.

A term “junction box” is often used in a case of distributing electrical power to multiple systems. A term “fuse box” is often used in a case of storing fuses or fusible links that interrupt circuits against anomalies such as overcurrent. A term “power-supply box” is often used in a case of achieving a switching function by storing relays in addition to the functions of a junction box and a fuse box. JP2016-72764A discloses a power-supply box.

### SUMMARY OF THE INVENTION

Recently, electrical components installed in a vehicle increase, and thereby devices stored in a power-supply box also increase. Concurrently, electrical power consumed by each of the electrical components also increases, and heats produced by parts in the power-supply box corresponding to the above electrical components also increase. As the result, heat generated at the power-supply box tends to increase, and appropriate heat radiation is desired. A metal heatsink, which is made from an extruded aluminum member, is often used for heat radiation. If we try to increase heat radiation of the heatsink more, a volume of the heatsink would increase. It may cause weight increase of the power-supply box. In recent years, in view of environmental issues, there is a strong demand for reducing carbon dioxide emissions from vehicles, in other words, a strong demand for improving fuel economy. In order to improve fuel economy, the total vehicle weight should be reduced, and thereby there is a very high demand for weight reduction of each of various equipment installed in vehicles. Therefore, weight increase of a power-supply box is a problem that cannot be overlooked.

An object of the present disclosure is to provide a power-supply box for a vehicle that can achieve appropriate heat radiation while avoiding its weight increase.

A power-supply box for a vehicle according to the present disclosure includes a circuit board on which a part is mounted, and a heatsink that is thermally contacted with the part on the circuit board to radiate heat produced by the part. The part produces the heat when a power supply output is supplied to the part. The heatsink is made of resin and a metal plating layer is formed on a surface of the heatsink.

According to the power-supply box, it is possible to achieve appropriate heat radiation while avoiding its weight increase.

### BRIEF DESCRIPTION OF DRAWINGS

FIG. 1 is a block diagram of a vehicle provided with a power-supply box according to an embodiment;

FIG. 2 is a perspective view illustrating a front face of the power-supply box;

FIG. 3 is an exploded perspective view illustrating the front face of the power-supply box;

FIG. 4 is a perspective view illustrating a back face of the power-supply box;

FIG. 5 is a front view of a print circuit board housed in the power-supply box;

FIG. 6 is a bottom view of the power-supply box; and

FIG. 7 is a perspective view of a blade fuse that is attached to a fuse connector of the power-supply box.

### DETAILED DESCRIPTION OF THE INVENTION

Hereinafter, a power-supply box 1 for a vehicle according to an embodiment will be described in detail with reference to the drawings. Note that “upper”, “lower”, “left” and “right” in following descriptions are upper, lower, left and right in each drawing, respectively, for explanation convenience, and the terms don't restrict an installation orientation of the power-supply box 1.

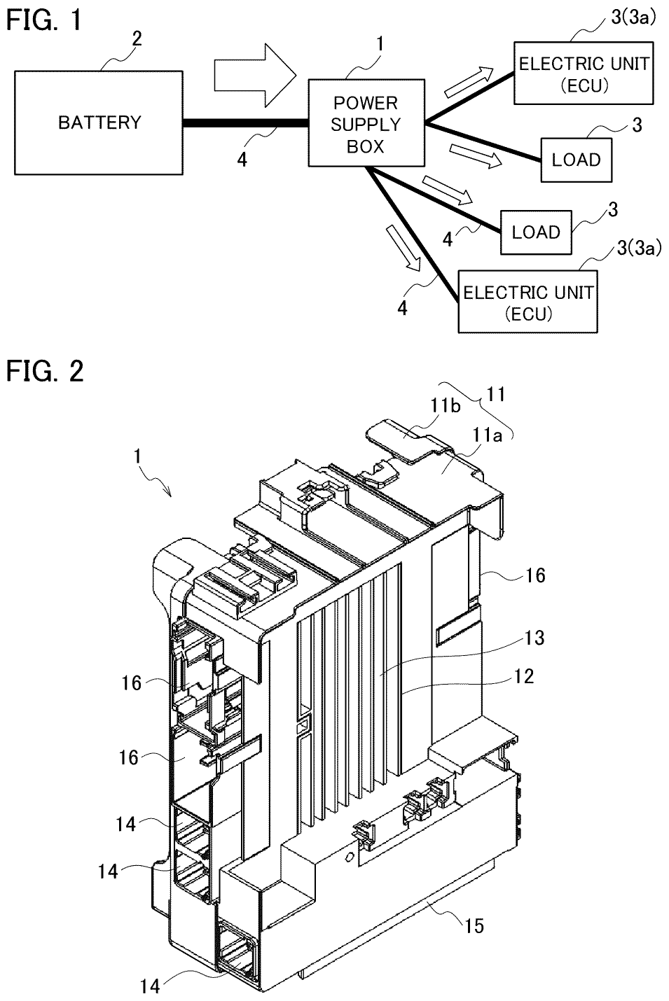

As illustrated in a block diagram of FIG. 1, the power-supply box 1 is electrically connected with a battery 2 that serves as a main power supply of a vehicle via a wire harness 4. Note that, although not illustrated in FIG. 1, the power-supply box 1 is also connected with an alternator that serves as another main power supply. The output of the battery 2 or the alternator is supplied to the power-supply box 1. The power-supply box 1 is also electrically connected with plural loads 3 that are various electrical components installed in the vehicle via wire harnesses 4. Electric units 3a such as ECU's that control the various electrical components are included in the loads 3. For example, the loads 3 with large power consumption include an air-conditioner, headlamps and various heaters built in a rear window, side mirrors, seats, a steering wheels and so on.

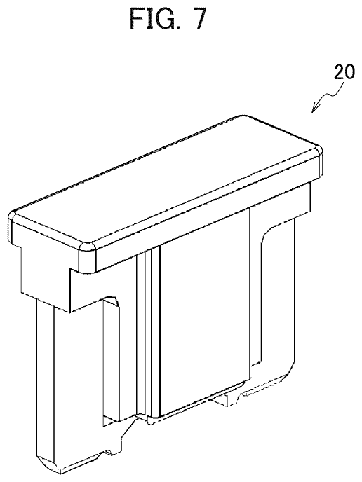

The power-supply box 1 has a function for distributing the power supply output to be supplied to the loads 3. Due to this power distribution, it becomes possible to use the wire harnesses 4 each having an appropriate wire diameter suitable for an electrical current to its corresponding load 3. In other words, magnitude of the electrical current flowing in the power-supply box 1 is much larger than in the electrical current flowing in each load 3, and thereby heat generated at the power-supply box 1 becomes very large. If a circuit are shorted when distributing the power supply output, it would cause overcurrent and there is a potential that the wire harnesses 4 and the electrical components would be damaged by the overcurrent. The power-supply unit 1 is connected with the loads 3 on circuits possessing such a potential through the wire harnesses 4 via fuses or fusible links. Since the circuits are disconnected by the fuses and the fusible links upon the overcurrent, the wire harnesses 4 and the electrical components can be protected. Hereinafter, disconnecting parts such as the fuses and the fusible links are merely referred to as fuses. In the present embodiment, so-called blade fuses 20 (hereinafter, merely called as the fuse(s) 20) as illustrated in FIG. 7 are used with being connected to an after-described fuse connector 15.

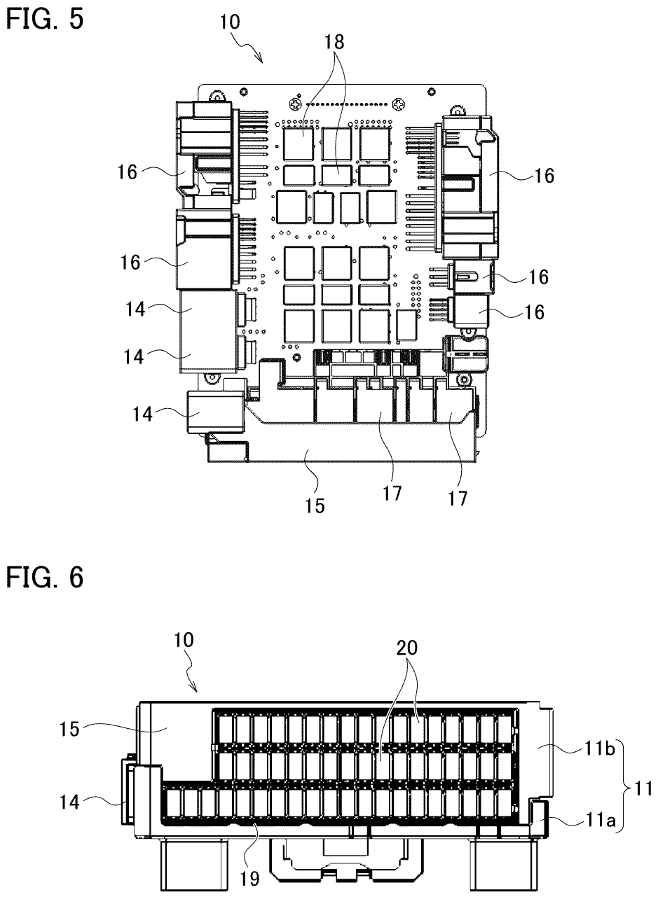

With respect to the loads 3 whose operations are activated and deactivated, their switching is done by relays 18 (see FIG. 5). For example, in a case where the load 3 is the above-mentioned air-conditioner, its circuit is activated by the relay 18 when a user in the vehicle operates an air-conditioner activation switch, and then the electrical power is supplied to the air-conditioner that serves as the load 3. Note that there may be a case where the load 3 whose corresponding relay 18 is automatically operated based on a detection result of a sensor. The fuses 20 are collectively stored in the fuse connector 15 of the power-supply box 1. Therefore, if the power supply to the load 3 is shut off by the fuse 20, the user can look for the cut-out fuse 20 in the fuse connector 15 to replace it. Therefore, the power-supply box 1 can improve maintenance workability.

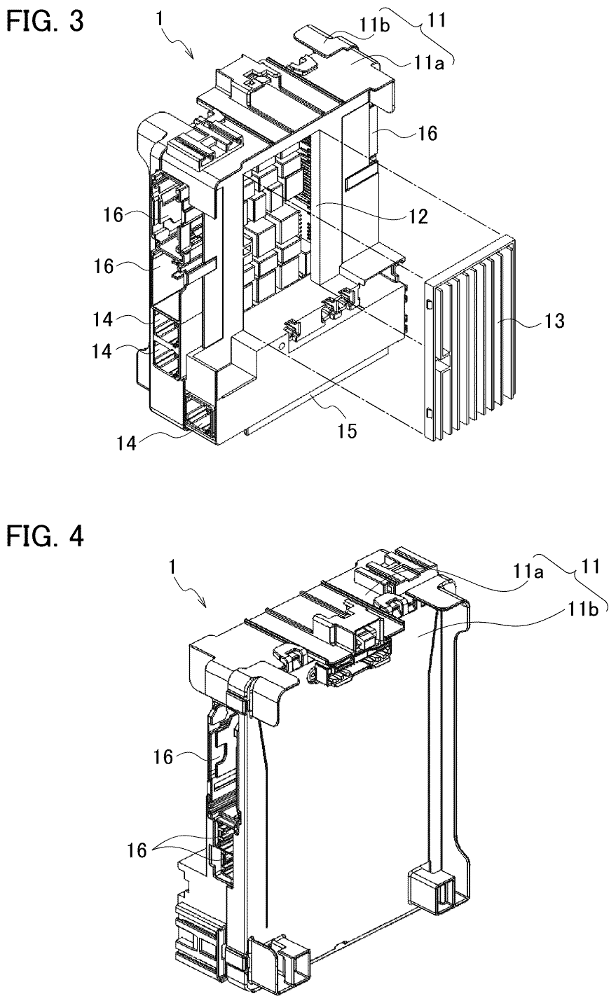

Next, configuration of the power-supply box 1 according to the present embodiment will be described with reference to FIG. 2 to FIG. 5. The power-supply box 1 includes a circuit board 10 in its housing 11. The relays 18, the fuse connector 15 (the fuses 20) and so on are installed on the circuit board 10. The housing 11 includes a first half housing 11a that is made of resin and covers one surface of the circuit board 10 and a second half housing 11b that is also made of resin and covers the other surface of the circuit board 10 that is the reverse surface of the one surface. The circuit board 10 is fixed with the second half housing 11b by screws, and the first half housing 11a is attached to the second half housing 11b so as to sandwich the circuit board 10 between them. The circuit board 10 is protected from external forces, dusts, water and so on by the housing 11.

The relays 18 are parts that produce heats when the output of the main power supply such as the battery 2 is supplied thereto. The power-supply box 1 also includes a heatsink 13 that is thermally contacted with the relays 18 on the circuit board 10 to radiate heats of the relays 18. The phrase “thermally contacted” means being contacted such that the heats of the relays 18 are transferred to the heatsink 13. In other words, the “thermally contacted” state includes a state where the two are physically contacted directly with each other, and a state where the two are contacted with each other with a heat radiation sheet or a thermally-conductive grease interposed therebetween. In the present embodiment, an opening 12 for exposing the heatsink 13 is formed in the first half housing 11a in order not to inhibit the heat radiation from the heatsink 13 thermally contacted with the relays 18.

The circuit board 10 is further provided with input connectors 14, output connectors 16 and busbars 17 in addition to the fuse connector 15 and the relays 18 that are already described above. Each connection port of the input connectors 14, the fuse connector 15 and the output connectors 16 are exposed on side faces of the housing 11 when the circuit board 10 is housed in the housing 11.

The input connectors 14 are connectors to which the output of the main power supply such as the battery 2 is supplied. The three input connectors 14 are provided in the present embodiment. The two input connectors 14 other than the input connector 14 illustrated at the lower left in FIG. 5 are provided to have a single integrated connector housing. The fuse connector 15 is a connector to which the plural fuses 20 are attached as illustrated in FIG. 6. The input connector 14 at the lower left in FIG. 5 and the fuse connector 15 are provided to have a single integrated housing in the present embodiment. The output connectors 16 are connectors that output the electrical power to the loads 3. The five output connectors 16 are provided in the present embodiment. The two output connectors 16 on the left side in FIG. 5 are provided to have a single integrated connector housing.

The plural busbars 17 are provided on the circuit board 10 along the fuse connector 15. A receptacle port 19 to which the plural fuses 20 are connected is formed at the bottom of the fuse connector 15 as illustrated in FIG. 6. The power supply output that is input to the input connector 14 at the lower left in FIG. 5 is distributed and then output from the output connector 16 at the upper right in FIG. 5 through the fuses 20 in the fuse connector 15 which have capacities suitable for the destination loads 3, the busbars 17 and the relays 18. The wire harnesses 4 connected to the output connector 16 at the upper right is branched and then connected to the destination loads 3.

The relay(s) 18 in the present embodiment is a sealed relay in a form of a box-shaped resin package, and the plural relays 18 are mounted at the center of the circuit board 10. Although the twenty relays 18 are provided in the present embodiment, the nineteen relays 18 other than the relay 18 at the lower right in FIG. 5 faces the opening 12 to be thermally contacted with the heatsink 13. The power supply output that is input to the two input connectors 14 other than the input connector 14 at the lower left is distributed and then output from the output connectors 16 through the relays 18 depending on the destination loads 3. The wire harnesses 4 connected to the plural output connectors 16 are connected to the destination loads 3 after being branched or unbranched.

The heatsink 13 in the present embodiment is made of resin, and provided with many heat-radiation fins that expand a heat radiation surface area of the heatsink 13. The heatsink 13 is fitted in the opening 12 formed on the first half housing 11a, and its back face is thermally contacted with the top faces of the resin packages of the above-mentioned nineteen relays 18. Heat is generated much at the power-supply box 1 to which the power supply output is supplied as described above, the surface area, i.e., the volume of the heatsink 13 may be subject to be large in view of the heat radiation of the generated heat. However, the heatsink 13 in the present embodiment is made of resin and lighter in weight than a metal heatsink, and thereby the heatsink 13 can highly contribute vehicle weight reduction. As a result, as mentioned above, the power-supply box 1 according to the present embodiment makes a significant contribution to reducing carbon dioxide emissions by reducing vehicle weight, i.e., contribution to improving fuel economy.

In addition, the power-supply box 1 in the present embodiment is fixed to the vehicle body by using a bracket(s). If it were provided with a metal heatsink with a large volume, its vibrations would become worse and the bracket should be reinforced. If a new reinforced bracket must be made, its manufacturing cost and its weight may increase. However, these increases of the cost and the weight can be prevented by the power-supply box 1 according to the present embodiment.

Thermal conductivity of the resin heatsink 13 is inferior to that of a metal heatsink. Therefore, a metal plating layer is formed on a surface of the heatsink 13 of the present embodiment in order to improve its thermal conductivity. The metal plating layer is formed on an entire of the surface of the heatsink 13. The formation of the metal plating layer can compensate for the reduced thermal conductivity of the resin heatsink 13. In addition, the metal plating layer can improve not only the thermal conductivity but also the heat radiation performance, because it is formed on the surface of the heatsink 13 that is most suitable for the heat radiation. A metal heatsink is generally made from an extruded aluminum member or by die-casting, but the resin heatsink 13 with the metal plating layer can be manufactured at lower cost than a manufacturing cost of the metal heatsink. The manufacturing cost of the heatsink 13 can be made more reduced that that of the metal heatsink. Note that the increase in the weight of the heatsink 13 due to the formation of the metal plating layer is minimal.

When the plural relays 18 are provided within the power-supply box 1 like as in the present embodiment, heats radiated from adjacent ones of the relays 18 may promote each other and the thermal interaction may cause an overall temperature rise. However, the temperature of each of the relays 18 can be reduced by the heatsink 13 in the present embodiment, so that the temperature rise due to the thermal interaction can be restricted. Therefore, the overall temperature of the power-supply box 1 can be reduced.

Recently, electrical components installed in a vehicle increase, many semiconductor parts are mounted on the circuit board 10 of the power-supply box 1. We would like to handle soldering of the relays 18 and the semiconductor parts onto the circuit board 10 only through a reflow process in order to restrict costs for manufacturing facilities. However, in that case, hot air during the reflow process may cause the air inside the sealed relays 18 to expand, which may damage the hermeticity of their packages. Changing the relays 18 from a sealed package to a non-sealed package could be considered, but would increase costs. According to the power-supply box 1, the reflow process of the sealed relays 18 can be done appropriately while the relays 18 are thermally contacted with the heatsink 13 that can radiate heats of the relays 18.

Since the power-supply box 1 in the present embodiment is installed in the vehicle, it is also expected that the environment in which the vehicle is located will be below zero degrees Celsius. When the environment becomes below zero, it is concerned that the contact terminals of the relays 18 of the power-supply box 1 may freeze and malfunction. The freezing may be accelerated by so-called “thermal dissipation” from the relays 18 through wirings printed on the circuit board 10 and the connected wire harnesses 4. The wire harnesses 4 connected to the power-supply box 1 have a relatively large diameter, because the power-supply box 1 copes with the electrical power from the main power supply, so that the heats may be easily lost due to the “thermal dissipation”. If the temperature inside the power-supply box 1 is relatively high but the contact terminals of the relays 18 are cooled by the “thermal dissipation”, the temperature difference of them causes dew condensation and then freezing. Therefore, by providing the heatsink 13, the temperature difference between the ambient temperature and the contact terminals inside the relays 18 can be reduced to prevent freezing.

Note that, in the present embodiment, the part that produces heat due to the power supply output and is thermally contacted with the heatsink 13 for its heat radiation, is the relay 18. But such a part is not limited to the relay 18. There is a fuse having a sealed resin package, and there is a semiconductor part that produces heat. These parts also produce heats due to the power supply output, and may be thermally contacted with the heatsink 13.

The power-supply box 1 according to the above embodiment includes the heatsink 13 that is thermally contacted with the part (the relays 18) that is mounted on the circuit board 10 and produces heat due to the supply of the power supply output (such as the output of the battery 2) to radiate the heat of the part (the relays 18). The heatsink 13 is made of resin and the metal plating layer is formed on its surface. Since the heatsink 13 is made of resin, weight increase of the power-supply box 1 can be prevented. Since the metal plating layer is formed on the surface of the heatsink 13, the thermal conductivity of the heatsink 13 made of resin can be improved. In other words, according to the power-supply box 1 of the above embodiment, it is possible to achieve appropriate heat radiation while avoiding its weight increase.

In addition, the power-supply box 1 according to the above embodiment further includes the housing 11 that houses the circuit board 10. The housing 11 includes the first half housing 11a that covers the one surface of the circuit board 10 and the second half housing 11b that covers the other surface of the circuit board 10. The opening 12 for exposing the heatsink 13 is formed in one of the first and second half housings 11a and 11b. In the above embodiment, the opening 12 is formed in the first half housing 11a. Therefore, the circuit board 10 and the parts (the busbars 17, the relays 18 and so on) mounted on the circuit board 10 can be protected by the housing 11 from external forces, dusts, water and so on. Furthermore, the heat radiation of the heatsink 13 can be ensured by exposing the heatsink 13 through the opening 12 formed in one of the first and second half housings 11a and 11b so that the heats produced by the parts doesn't stagnate in the housing 11.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A power-supply box for a vehicle comprising:
a circuit board on which a part is mounted, the part producing heat when a power supply output is supplied to the part; and
a heatsink that is thermally contacted with the part on the circuit board to radiate the heat of the part,
wherein the heatsink is made of resin and a metal plating layer is formed on a surface of the heatsink.

2. The power-supply box according to claim 1, further comprising
a housing that houses the circuit board,
wherein the housing includes a first half housing that covers one surface of the circuit board and a second half housing that covers another surface of the circuit board, and
wherein an opening through which the heatsink is exposed is formed in one of the first half housing or the second half housing.
